(19) United States
(12) Patent Application Publication
(10) Pub. No.: US 2026/0060079 A1
(43) Pub. Date: Feb. 26, 2026

(54) Bonding Layer with Metallization Features

(71) Applicant: Applied Materials, Inc., Santa Clara, CA (US)

(72) Inventor: Yoocharn JEON, Palo Alto, CA (US)

(21) Appl. No.: 18/812,228

(22) Filed: Aug. 22, 2024

(51) Int. Cl. H01L 23/373; H01L 21/02; H01L 21/20; H01L 23/14

(52) U.S. Cl. CPC H01L 23/3738; H01L 21/02019; H01L 21/2007; H01L 23/147

(57) ABSTRACT

Methods and structures relating to bonding wafers using an aluminum nitride bonding layer with embedded metallization features. In some embodiments, the method may comprise forming a bonding layer on a first wafer where the bonding layer is formed of epitaxially grown aluminum nitride and where the first wafer is a silicon-based material and forming one or more metal features into the bonding layer on the first wafer. The first wafer may be hybrid bonded to a second wafer or die with one or more second metal features surrounded by a diffusion barrier layer. The one or more second metal features of the second wafer or die bonds to the one or more metal features of the first wafer. The diffusion barrier layer of the second wafer or die bonds, at least, to the bonding layer of the first wafer.

### FIELD

Embodiments of the present principles generally relate to semiconductor processing of semiconductor substrates.

### BACKGROUND

Semiconductor devices are formed on wafers called device wafers. The device wafers include the actual device and also a metallization stack that provides connections to the device for power and signals. Heat generated by the operation of the semiconductor devices needs to be removed to maintain performance of the devices. A carrier wafer or heat spreader may be applied to the device wafer to allow dissipation of the heat into the heat spreader. The inventors have observed, however, that the metallization stack presents a significant thermal resistance to the removal of the heat from the device to the heat spreader, resulting in higher device temperatures.

Accordingly, the inventor has provided methods and structures that improve the thermal performance characteristics of a device wafer bonded to a carrier wafer.

### SUMMARY

Methods and structures that improve the thermal performance characteristics of bonded wafers are provided herein.

In some embodiments, a method for bonding may comprise forming a bonding layer on a first wafer where the bonding layer comprises aluminum nitride and the first wafer is a silicon-based material and forming one or more metal features into the bonding layer on the first wafer.

In some embodiments, the method may further include a bonding layer that has a thickness of approximately 200 nanometers to approximately 10 micrometers, one or more metal features that have a thickness of approximately 200 nanometers to approximately 500 nanometers, forming the one or more metal features comprises forming at least one opening into the bonding layer, depositing a first diffusion barrier layer over the bonding layer where the first diffusion barrier layer is a conformal layer, depositing a metal material over the first diffusion barrier layer, and performing a chemical mechanical planarizing (CMP) process to remove the first diffusion barrier layer from an uppermost surface of the first wafer and to expose the uppermost surface of the bonding layer and the uppermost surface of the one or more metal features, a first diffusion barrier layer that is tantalum nitride (TaN), a first wafer that is silicon with a (111) crystal structure orientation at an uppermost surface on which the bonding layer is formed and a bonding layer that is substantially formed of an epitaxial aluminum nitride, a first wafer that is 4H-silicon carbide with a (001) crystal structure orientation at an uppermost surface on which the bonding layer is formed and a bonding layer that is substantially formed of an epitaxial aluminum nitride, hybrid bonding the first wafer to a second wafer or die where the second wafer or die has one or more second metal features that bond with the one or more metal features of the first wafer, a second wafer or die that has a second diffusion barrier layer that surrounds the one or more second metal features and bonds to at least the bonding layer of the first wafer, a second diffusion barrier layer that is silicon carbon nitride (SiCN), a second wafer or die that has a metallization stack that includes the one or more second metal features and has a thickness of approximately 1 micrometer, one or more metal features that have a first width that is smaller than a second width of the one or more second metal features, and/or a second wafer or die that has a metallization stack that thermally connects a device on the second wafer or die to the one or more metal features of the first wafer and to a heat spreader of the first wafer.

In some embodiments, a heat spreader structure may comprise a heat spreader layer, a bonding layer comprising aluminum nitride on the heat spreader layer, and one or more metal features embedded into the bonding layer comprising aluminum nitride.

In some embodiments, the heat spreader structure may further include a bonding layer comprising aluminum nitride that has a thickness of approximately 200 nanometers to approximately 10 micrometers, a heat spreader layer that is silicon with a (111) crystal structure orientation at an interface between the heat spreader layer and the bonding layer comprising aluminum nitride and where the bonding layer comprising aluminum nitride is substantially formed of an epitaxial aluminum nitride, a heat spreader layer that is 4H-silicon carbide with a (001) crystal structure orientation at an interface between the heat spreader layer and the bonding layer comprising aluminum nitride and where the bonding layer comprising aluminum nitride is substantially formed of an epitaxial aluminum nitride, a heat spreader structure that is bonded to a second wafer or die where the second wafer or die has a silicon carbon nitride (SiCN) diffusion barrier layer surrounding one or more second metal features, the one or more second metal features are bonded to the one or more metal features, and the SiCN diffusion barrier layer is bonded, at least, to the bonding layer comprising aluminum nitride, and/or one or more metal features that have vertical interconnects and horizontal interconnects.

In some embodiments, a non-transitory, computer readable medium having instructions stored thereon that, when executed, cause a method for bonding wafers, the method may comprise forming a bonding layer on a first wafer where the bonding layer comprises aluminum nitride and the first wafer is a silicon-based material and forming one or more metal features into the bonding layer on the first wafer.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of bonding wafers or wafers to dies in accordance with some embodiments of the present principles.

FIG. 2 depicts an isometric view of a carrier wafer undergoing a preparation process in accordance with some embodiments of the present principles.

FIG. 3 depicts an isometric view of a formation process of a bonding layer on a carrier wafer in accordance with some embodiments of the present principles.

FIG. 4 depicts a cross-sectional view of an opening formed in a bonding layer on a carrier wafer in accordance with some embodiments of the present principles.

FIG. 5 depicts a cross-sectional view of a diffusion barrier layer being formed on a bonding layer on a carrier wafer in accordance with some embodiments of the present principles.

FIG. 6 depicts a cross-sectional view of a metal material deposited on a carrier wafer in accordance with some embodiments of the present principles.

FIG. 7 depicts a cross-sectional view of a metallization feature in a bonding layer on a carrier wafer in accordance with some embodiments of the present principles.

FIG. 8 depicts an isometric view of a device wafer undergoing a preparation process in accordance with some embodiments of the present principles.

FIG. 9 depicts a cross-sectional view of metallization stack formed on a device wafer or a die in accordance with some embodiments of the present principles.

FIG. 10 depicts a cross-sectional view of a diffusion barrier layer being formed on a device wafer or a die in accordance with some embodiments of the present principles.

FIG. 11 depicts a cross-sectional view of a carrier wafer with a bonding layer being bonded to a device wafer or die in accordance with some embodiments of the present principles.

FIG. 12 depicts a cross-sectional view of a bonded wafer or bonded wafer to die and heat transfer through the bonded wafer or bonded wafer to die in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and structures provide improved thermal performance of a first wafer bonded to a second wafer such as a carrier wafer and a device wafer or between a wafer and a die such as a carrier wafer and one or more dies and the like. The techniques transfer a portion of a traditional metallization stack of a device wafer or die to a bonding layer on the carrier wafer. The bonding layer has higher thermal conductivity than the low k dielectric material of the metallization stack. By reducing the overall thickness of the metallization stack, the thermal resistance of the metallization stack is reduced, allowing for a substantial reduction of device temperatures for devices on the device wafer. In some cases, the metallization stack may be reduced in thickness by 30% or more. Another benefit of the present techniques is the simplification of the metallization stack formation on the device wafer or die.

When backside power deliver networks (BSPDN) are employed, the heat generated by the semiconductor devices on a device wafer or die must be removed through a thick stack of metallization, where the thermal conduction is poor, and the carrier wafer (heat spreader). Traditionally, the top-level metallization layer of the device wafer or die is the thickest layer of the metallization stack and is embedded in the low k dielectric material of the device wafer or die. The low k dielectric material is a poor thermal conductor which adds to the thermal resistance of the metallization stack of the device wafer or die and, in turn, raises the temperature of the device on the device wafer or die. The inventor has discovered that by moving the top-level metallization layer of the device wafer or die to the bonding layer on the carrier wafer, the metallization stack thickness can be decreased along with the thermal resistance of the metallization stack, lowering the device temperatures substantially.

In the present techniques, the top-level metallization layer of the device wafer or die is embedded in a thermally conductive, electrically insulating bonding layer that is formed on the carrier wafer. The remaining metallization stack of the device wafer or die is then bonded to the top-level metallization layer embedded in the bonding layer. The embedded top-level metallization layer in the bonding layer is surrounded by high thermally conductive material rather than the low thermally conductive material of the device wafer or die, increasing the thermal dissipation rate of the device in the device wafer or die into the carrier wafer (heat spreader). The structure of the present techniques is accomplished without introducing any high thermal resistance interfaces and moving the top-level metallization process to the carrier wafer from the device wafer or die. By replacing the low k dielectric material surrounding the top-level metallization layer of the device wafer or die with a thermally conductive material on the carrier wafer, the thermal resistance of the metallization stack of the device wafer or die is reduced without any additional process burden.

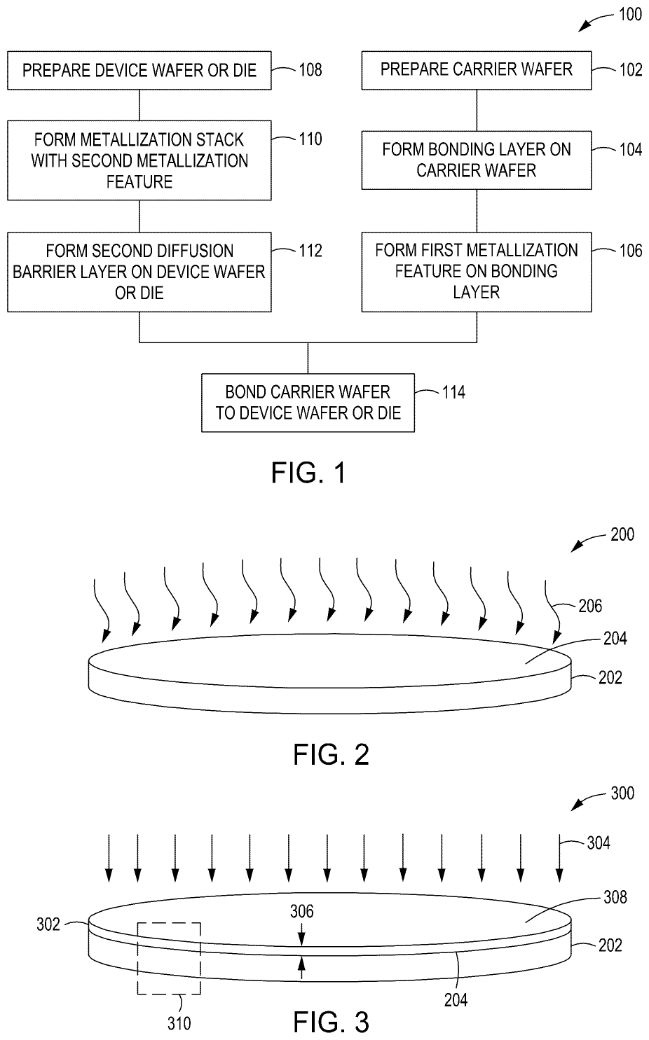

As used herein, a carrier wafer is a silicon-based wafer that may be used to provide support for a device wafer or die and/or as a heat spreader for devices on the device wafer or die. The carrier wafer, in some embodiments, may have no metallization or some amount of metallization. The bonding techniques of the present principles are not limited to only bonding device wafers, dies, and carrier wafers. The techniques are equally applicable to bonding of other types of wafers and the like and even to singulated device chips and heat sinks and the like. A device wafer, a die, and a carrier wafer are only used for the sake of brevity in the following examples. FIG. 1 is a method 100 of the present techniques for wafer-to-wafer bonding such as, but not limited to, a device wafer and a carrier wafer and/or wafer-to-die bonding such as, but not limited to, a die and a carrier wafer and the like. The carrier wafer in the following examples is unique in that the bonding layer is formed on the carrier wafer rather than on the device wafer or die. The bonding layer material, aluminum nitride, requires high temperatures for deposition (e.g., 600 degrees Celsius or higher) which are not compatible with the low thermal budgets (e.g., less than 400 degrees Celsius) of the devices on the device wafer or die. In order to promote high quality epitaxial growth of aluminum nitride on the carrier wafer, the carrier wafer may be a Si material with a crystal structure orientation on the bonding surface of (111) or a 4H-SiC material with a crystal structure orientation on the bonding surface of (011) and the like.

In block 102, an epitaxial growth surface 204 of a first wafer or carrier wafer 202 is prepared for forming a bonding layer as depicted in a view 200 of FIG. 2. The bonding layer is used to substantially increase the bonding strength between the first wafer and a second wafer or die versus bonding the materials of the first wafer and the second wafer or die. As the carrier wafer 202 is a silicon-based material, the epitaxial growth surface 204 is prone to oxidation when exposed to the atmosphere. The resulting oxide is amorphous and inhibits epitaxial growth. The oxide may be removed to enhance the formation of the bonding layer. If the carrier wafer 202 is maintained in an oxygen free environment without contamination and/or oxidation of the bonding surface (or if certain bonding layer formation techniques are used, discussed below), the bonding surface preparation may not be performed. A pre-deposition clean process 206 may be performed to prepare the epitaxial growth surface 204 to improve the epitaxial nucleation on the epitaxial growth surface 204. The pre-deposition clean process 206 may be a plasma etching process (dry etch process), a plasma sputtering process, and/or a hydrogen fluoride-based process (e.g., wet etch process using hydrofluoric acid-based process, etc.) and the like.

To promote epitaxial growth, the pre-deposition clean process 206 should preserve the underlying crystal structure of the carrier wafer 202 and not roughen or damage the crystal structure of the epitaxial growth surface 204. A plasma sputtering process can be used but care must be taken to avoid crystal structure damage to the carrier wafer. In general, the hydrogen fluoride-based process is more controllable and produces less surface damage. In the alternative, the epitaxial growth surface 204 may be prepared by removing the oxide and/or contaminants with an aluminum deposition clean process that includes depositing aluminum which then reacts with and forms a thin oxygen-containing aluminum nitride layer on the epitaxial growth surface 204. Aluminum has a higher affinity to oxygen than silicon. The deposition of the aluminum reduces, for example, silicon dioxide on the epitaxial growth surface 204 to silicon. In some embodiments, a thickness of the thin oxygen-containing aluminum nitride layer may be from greater than zero to approximately 2 nm. At the completion of the aluminum deposition clean process, nitrogen gas can be added into the process to begin the epitaxial growth of aluminum nitride for the formation process of the bonding layer on a surface of the thin oxygen-containing aluminum nitride layer.

In block 104, a bonding layer 302 is formed by an epitaxial growth process 304 on the epitaxial growth surface 204 (or the surface of the thin oxygen-containing aluminum nitride layer) of the carrier wafer 202 as depicted in a view 300 of FIG. 3. The epitaxial growth process 304 grows aluminum nitride with a single crystal structure or well-aligned crystallite structures on the carrier wafer 202. Epitaxial growth of aluminum nitride on a silicon-based wafer eliminates the small grain boundaries so that the total crystal structure quality throughout the thickness of the layer will be much higher. A thickness 306 of the bonding layer 302 may be from approximately 200 nanometers to approximately 10 micrometers. The bonding layer 302 has an increased thickness to allow for the formation of a top-level metallization layer in the bonding layer 302 instead of forming the top level-metallization layer on the metallization stack of a device wafer. A bonding surface 308 is formed by the uppermost surface of the bonding layer 302.

In some embodiments, the epitaxial growth process 304 may include a physical vapor deposition (PVD) process, a metal organic chemical vapor deposition (MOCVD) process, and/or a molecular-beam epitaxy (MBE) process and the like. The PVD process is the most economical process with the MOCVD and MBE processes increasing in cost and processing time, respectively. MOCVD produces a higher quality grain growth than PVD while MBE produces the highest quality at the highest expense. The PVD process may also alternate the reagent gas between ammonia gas and nitrogen gas to enhance the crystal quality of the aluminum nitride. In some embodiments, a high temperature process (e.g., a PVD process or an MOCVD process at approximately 750 degrees Celsius or greater) may be used for preparing the epitaxial growth surface of the carrier (block 102), as the high temperature can remove the oxide from the epitaxial growth surface 204 as well as grow epitaxial aluminum nitride on the epitaxial growth surface 204. The present techniques are not limited to the above epitaxial growth processes for aluminum nitride and any other process for producing high quality single crystal or well-aligned crystallite aluminum nitride may be used.

To reduce grain boundaries and increase the quality of the epitaxial aluminum nitride, the epitaxial growth process 304 may be performed at high temperatures (e.g., 600 degrees Celsius to 850 degrees Celsius or more). Higher growth temperatures yield superior grain structures of the aluminum nitride which increases the thermal conductivity of the aluminum nitride. Such high process temperatures are not compatible with the device wafer or die which have a thermal budget of 400 degrees Celsius or less. The low thermal budget of the device wafer or die is due to the semiconductor device structures and/or metallization found on the device wafer and die. The low thermal budget requirement of the device wafer would yield poor crystal quality of epitaxial aluminum nitride at temperatures of 400 degrees Celsius or less. In addition, the device wafer or die is generally formed of silicon with a crystal orientation of (100) which is an industry standard. High quality single crystal or well-aligned crystallite aluminum nitride cannot be grown epitaxially on silicon with a crystal orientation of (100). Moreover, the device wafer or die may have various amorphous films deposited on the surface, on which an epitaxial growth is not possible.

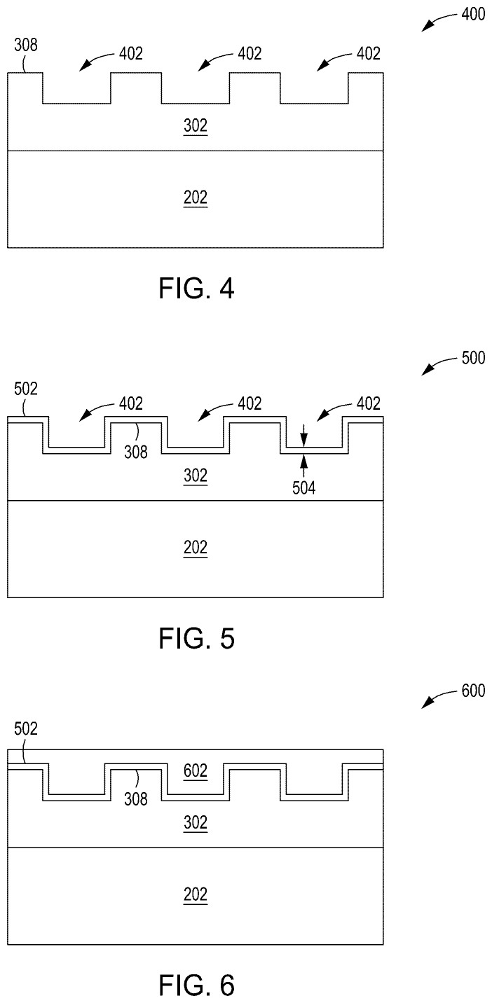

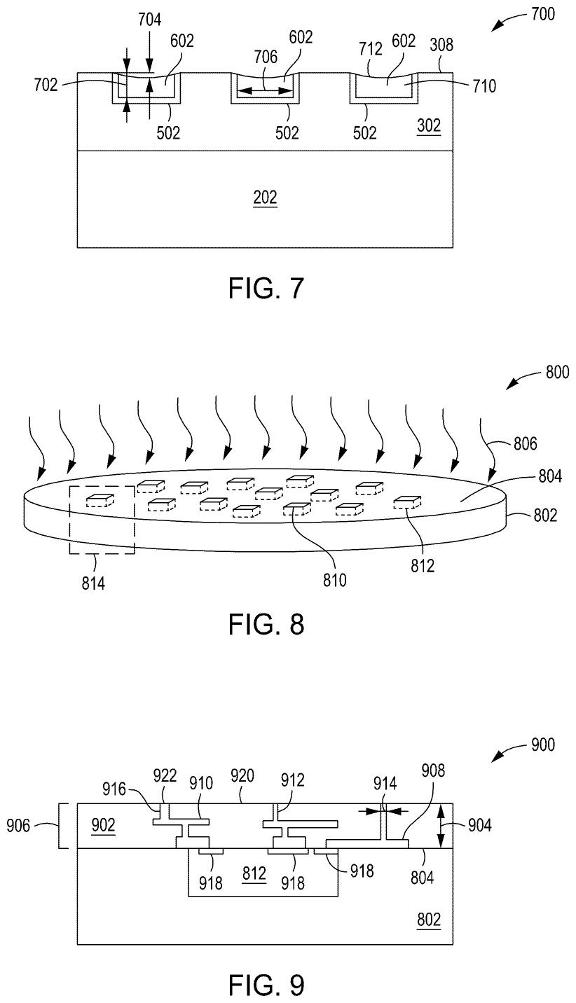

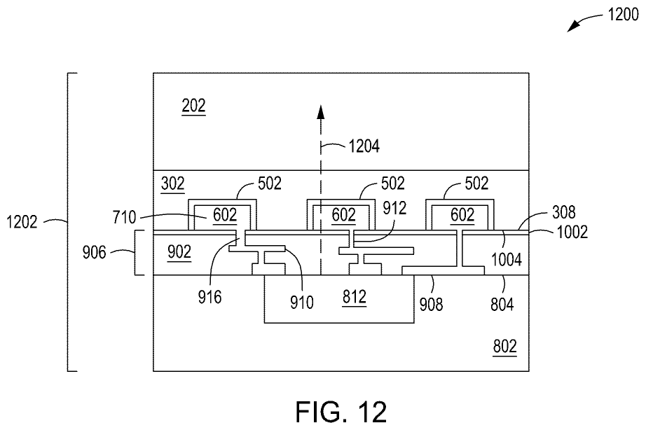

In block 106, a first metallization feature 710 (see view 700 of FIG. 7) is formed into the bonding layer 302 of the first wafer or carrier wafer 202 as depicted in FIGS. 4-7. In some embodiments, the first metallization feature 710 may comprise one or more metal features. A view 400 of FIG. 4 (and views 500-700 of FIGS. 5-7 and views 1100-1200 of FIGS. 11-12) depict a cross-sectional portion 310 of the carrier wafer 202 with the bonding layer 302 as depicted in FIG. 3. An opening 402 is formed into the bonding layer 302 as depicted in the view 400 of FIG. 4. The opening 402 may be formed by masking an uppermost surface 308 of the bonding layer 302 and etching the bonding layer 302. Any etch process compatible with removal of aluminum nitride can be used to form the openings 402. In some embodiments, a first diffusion barrier layer 502 may be conformally deposited on the bonding layer 302 and into the openings 402 as depicted in the view 500 of FIG. 5. A thickness 504 of the first diffusion barrier layer 502 may be a monolayer to approximately 20 nanometers. The first diffusion barrier layer 502 prevents metal material (deposited in subsequent processes in the opening 402) from diffusing into the aluminum nitride of the bonding layer 302. In some embodiments, the first diffusion barrier layer 502 may be tantalum nitride and the like that prevents metal diffusion into the aluminum nitride.

A metal material 602, such as but not limited to copper and the like is deposited onto the first diffusion barrier layer 502 on the uppermost surface 308 of the bonding layer 302 as depicted in the view 600 of FIG. 6. The metal material 602, at least, fills the opening 402. A chemical mechanical planarizing (CMP) process is then used to remove the first diffusion barrier layer 502 from the uppermost surface 308 of the bonding layer 302 and to expose an uppermost surface 712 of the first metallization feature 710 in the bonding layer 302. In some embodiments, a thickness 702 of the first metallization feature may be approximately 200 nanometers to approximately 500 nanometers. The thickness 702 of the first metallization feature 710 can vary based on the types of devices in the device wafer and design criteria. In some embodiments, the first metallization feature 710 may have a recess 704 on the uppermost surface 712. During the CMP process, the metal material 602 may be removed faster than the material of the first diffusion barrier layer 502 causing the uppermost surface 712 of the first metallization feature 710 to be recessed and have a dished or curved profile. During hybrid bonding, the dielectric material surfaces of two layers being bonded engage first and then an annealing process causes further expansion or reflow of the metal materials to bond the metal materials. The recess 704 allows for the expansion of the metal material 602 of the first metallization feature 710 to bond with a second metallization feature 916 (see FIG. 9). In some embodiments, the recess 704 is not formed during the CMP process. In some embodiments, a width 706 of the first metallization feature 710 is greater than a width of the second metallization feature 916 (see FIG. 9).

The second wafer or device wafer or die 802 (FIG. 8 depicts a wafer with devices/dies but is also representative of a single die on which processes are performed similar to that of the second wafer or device wafer) typically has undergone prior processing for the formation of devices and other structures in a front end of line (FEOL) manufacturing facility. The device wafer or die 802 may then be transferred to a packaging facility (back end of line (BEOL)) where the device wafer or die 802 undergoes cleaning, metallization, and/or bonding processes as described herein. The processing of the second wafer or device wafer or die 802 may be performed in parallel to the processing of the first wafer or carrier wafer 202 or serially before or after the processing of the first wafer or carrier wafer 202. In block 108, a second wafer or device wafer or die 802 is prepared for a metallization process as depicted in a view 800 of FIG. 8. A metallization process forms layers of conductive interconnects and/or vias in a low k dielectric material, such as silicon oxides and/or silicon carbon oxides and the like, to provide internal and/or external connections and the like to inputs/outputs of a device 812 in the device wafer or die 802. Connection materials, such as copper, readily oxidize when exposed to the atmosphere. Pre-metallization clean processes 806 may be performed on the uppermost surface 804 of the device wafer or die 802 to clean contacts 810 of the device 812 and to prepare the dielectric material (remove contaminants, etc.) of the device wafer or die 802 before forming the metallization stack 906.

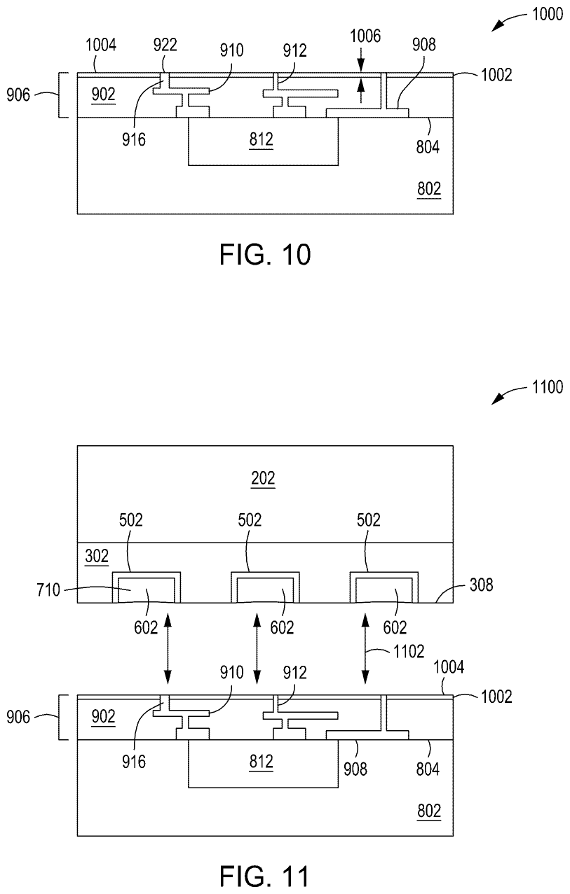

In block 110, the metallization stack 906 with a second metallization feature 916 is formed on the device wafer or die 802 as depicted in a view 900 of FIG. 9. In some embodiments, the second metallization feature 916 may comprise one or more second metal features. The view 900 of FIG. 9 (and views 1000-1200 of FIGS. 10-12) depict a cross-sectional portion 814 of the device wafer or die 802 as depicted in FIG. 8. The metallization stack 906 interfaces with the device 812 by providing horizontal and/or vertical interconnections that are embedded in an electrically isolating, low k dielectric material 902 such as, but not limited to, silicon oxides, silicon carbon oxides, and the like that have low thermal conductance. For example, a metallization layer 908 may provide a contact to a pad 918 directly on the device 812. The metallization layer 908 may be connected to a via 912 or another metallization layer 910 to reach an uppermost surface 920 of the metallization stack 906. In some embodiments, the exposed uppermost surface 922 of a via 912 or a metallization layer 910 forms a second metallization feature 916. A width 914 of the second metallization feature 916 is generally substantially smaller than the width of the first metallization feature 710 of the bonding layer 302 (see FIG. 7). In some embodiments, the second metallization feature 916 may be formed after deposition of a second diffusion barrier layer (discussed below).

In a conventional metallization stack formed on a device wafer, the conventional top-level metallization layer includes the first metallization feature 710 which increases the metallization stack height. In the present techniques, by moving the first metallization feature 710 (the top-level metallization layer) from the device wafer or die 802 to the carrier wafer 202, the thermal resistance of the metallization stack 906 is substantially reduced through the reduction of the thickness 904 of the metallization stack 906 and by placing the top-level metallization layer into high thermal conductance material (aluminum nitride of the bonding layer 302). In some embodiments, the reduction in thickness of the metallization stack 906 may be 30% or more over conventional thicknesses of metallization stacks on device wafers or dies. For example, a conventional metallization stack may be approximately 1.5 microns in height with a top-level metallization layer thickness of 0.5 microns. Moving the top-level metallization layer to the carrier wafer reduces the metallization stack thickness by 0.5 microns or to approximately 1.0 microns. In addition, a similar reduction in the device temperature can be obtained as the first metallization feature 710 is now surrounded by the high thermal conductive material of aluminum nitride of the bonding layer 302 of the carrier wafer 202 instead of the low thermally conductive material of low k dielectric of the metallization stack of the device wafer or die.

In block 112, in some embodiments, a second diffusion barrier layer 1002 may be formed on the device wafer or die as depicted in a view 1000 of FIG. 10. The second diffusion barrier layer 1002 may be deposited using processes that are compatible with deposition on low k dielectric materials of the metallization stack 906. A thickness 1006 of the second diffusion barrier layer 1002 may be a monolayer to approximately 100 nanometers. An uppermost surface 1004 of the second diffusion barrier layer 1002 will be bonded to the uppermost surface 308 of the bonding layer 302 in a subsequent bonding process. In some embodiments, the second diffusion barrier layer 1002 may be a silicon carbon nitride (SiCN) material. In some embodiments, the deposition process may include masking of the uppermost surface 922 of the second metallization feature 916 prior to the deposition of the second diffusion barrier layer 1002. In some embodiments, the second diffusion barrier layer 1002 may be deposited prior to the formation of the via 912 and the second metallization feature 916. The second diffusion barrier layer 1002 is deposited and then openings are formed in the low k dielectric material 902 down to the metallization layer 910 and metal gapfilled. A chemical mechanical planarization (CMP) process is then used to form the exposed uppermost surface 922. In some embodiments, the via 912 and/or the second metallization feature 916 may incorporate an additional barrier layer, different from the second diffusion barrier layer 1002, on the low k dielectric material 902 in the openings prior to the gapfilling process. The additional barrier layer may be similar to the first diffusion barrier layer 502.

The second diffusion barrier layer 1002 surrounds the uppermost surface 922 of the second metallization feature 916. The second diffusion barrier layer 1002 prevents diffusion of the metal material of the second metallization feature 916 and the first metallization feature 710 (after bonding) into any surrounding dielectric materials. The second diffusion barrier layer 1002 provides a diffusion barrier cap on the first metallization feature 710 after bonding, as the area of the uppermost surface 712 of the first metallization feature 710 is typically larger than the area of the uppermost surface 922 of the second metallization feature 916. Although not shown for the sake of brevity, the metallization stack 906 is formed with a diffusion barrier between the metal and the dielectric material as the metallization layers are formed.

In block 114, the first wafer or carrier wafer 202 with bonding layer 302 undergoes a bonding process 1102 to bond with the second wafer or device wafer or die 802 as depicted in a view 1100 of FIG. 11. The bonding process 1102 can be performed at approximately 400 degrees or less in accordance with the thermal budget constraints of the device wafer or die 802. The bonding process 1102 is a hybrid bonding process (mix of metal/dielectric materials, etc.) which may include a subsequent annealing process to increase the dielectric bonding strength and/or to reflow and enhance the metal bonding strength of the interconnects (e.g., first metallization feature 710 and second metallization feature 916, etc.). A bonded wafer 1202 is depicted in a view 1200 of FIG. 12. The bonded wafer 1202 includes the device wafer or die 802 and the carrier wafer 202 with the bonding layer 302. The first metallization feature 710 bonds with the second metallization feature 916 which electrically connects the metallization stack 906 of the device wafer or die 802 with the first metallization feature 710 (the conventional top-level metallization layer of a conventional device wafer). With the present techniques, the bonding layer 302 not only increases the bonding strength between the carrier wafer 202 and the device wafer or die 802 but also substantially decreases the thermal resistance of the metallization stack 906 by transferring a portion of the metallization stack 906 to the bonding layer 302 which has greater thermal conductivity. As the carrier wafer 202 acts as a heat spreader, lowering the thermal resistance between the device 812 and the heat spreader allows the heat 1204 of the device 812 to more easily traverse through the metallization stack 906, the bonding layer 302, and into the heat spreader, substantially reducing the temperature of the device 812.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for bonding, comprising:
forming a bonding layer on a first wafer, wherein the bonding layer comprises aluminum nitride and wherein the first wafer is a silicon-based material; and
forming one or more metal features into the bonding layer on the first wafer.

2. The method of claim 1, wherein the bonding layer has a thickness of approximately 200 nanometers to approximately 10 micrometers.

3. The method of claim 1, wherein the one or more metal features have a thickness of approximately 200 nanometers to approximately 500 nanometers.

4. The method of claim 1, forming the one or more metal features comprises:
forming at least one opening into the bonding layer;
depositing a first diffusion barrier layer over the bonding layer, wherein the first diffusion barrier layer is a conformal layer;
depositing a metal material over the first diffusion barrier layer; and
performing a chemical mechanical planarizing (CMP) process to remove the first diffusion barrier layer from an uppermost surface of the first wafer and to expose the uppermost surface of the bonding layer and the uppermost surface of the one or more metal features.

5. The method of claim 4, wherein the first diffusion barrier layer is tantalum nitride (TaN).

6. The method of claim 1, wherein the first wafer is silicon with a (111) crystal structure orientation at an uppermost surface on which the bonding layer is formed and wherein the bonding layer is substantially formed of an epitaxial aluminum nitride.

7. The method of claim 1, wherein the first wafer is 4H-silicon carbide with a (001) crystal structure orientation at an uppermost surface on which the bonding layer is formed and wherein the bonding layer is substantially formed of an epitaxial aluminum nitride.

8. The method of claim 1, further comprising:
hybrid bonding the first wafer to a second wafer or die, wherein the second wafer or die has one or more second metal features that bond with the one or more metal features of the first wafer.

9. The method of claim 8, wherein the second wafer or die has a second diffusion barrier layer that surrounds the one or more second metal features and bonds to at least the bonding layer of the first wafer.

10. The method of claim 9, wherein the second diffusion barrier layer is silicon carbon nitride (SiCN).

11. The method of claim 8, wherein the second wafer or die has a metallization stack that includes the one or more second metal features and has a thickness of approximately 1 micrometer.

12. The method of claim 8, wherein the one or more metal features have a first width that is smaller than a second width of the one or more second metal features.

13. The method of claim 8, wherein the second wafer or die has a metallization stack that thermally connects a device on the second wafer or die to the one or more metal features of the first wafer and to a heat spreader of the first wafer.

14. A heat spreader structure, comprising:
a heat spreader layer;
a bonding layer comprising aluminum nitride on the heat spreader layer; and
one or more metal features embedded into the bonding layer comprising aluminum nitride.

15. The heat spreader structure of claim 14, wherein the bonding layer comprising aluminum nitride has a thickness of approximately 200 nanometers to approximately 10 micrometers.

16. The heat spreader structure of claim 14, wherein the heat spreader layer is silicon with a (111) crystal structure orientation at an interface between the heat spreader layer and the bonding layer comprising aluminum nitride and wherein the bonding layer comprising aluminum nitride is substantially formed of an epitaxial aluminum nitride.

17. The heat spreader structure of claim 14, wherein the heat spreader layer is 4H-silicon carbide with a (001) crystal structure orientation at an interface between the heat spreader layer and the bonding layer comprising aluminum nitride and wherein the bonding layer comprising aluminum nitride is substantially formed of an epitaxial aluminum nitride.

18. The heat spreader structure of claim 14, wherein the heat spreader structure is bonded to a second wafer or die, wherein the second wafer or die has a silicon carbon nitride (SiCN) diffusion barrier layer surrounding one or more second metal features, wherein the one or more second metal features are bonded to the one or more metal features, and wherein the SiCN diffusion barrier layer is bonded, at least, to the bonding layer comprising aluminum nitride.

19. The heat spreader structure of claim 18, wherein the one or more metal features have vertical interconnects and horizontal interconnects.

20. A non-transitory, computer readable medium having instructions stored thereon that, when executed, cause a method for bonding wafers, the method comprising:
forming a bonding layer on a first wafer, wherein the bonding layer comprises aluminum nitride and wherein the first wafer is a silicon-based material; and
forming one or more metal features into the bonding layer on the first wafer.
